(19) United States
(12) Patent Application Publication
(10) Pub. No.: US 2007/0007670 A1
(43) Pub. Date: Jan. 11, 2007

(54) Reworkable bond pad structure

(76) Inventor: Te-Wei Chen, Chupei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/299,833

(22) Filed: Dec. 13, 2005

(30) Foreign Application Priority Data
Jul. 11, 2005 (TW) 94123418

(51) Int. Cl. H01L 23/48

(52) U.S. Cl. 257/786; 257/784; 257/781

(57) ABSTRACT

A bond pad structure includes a plurality of normal bond pads, a conductive structure and a plurality of backup bond pads. The conductive structure has a plurality of blocks, and at least one of the backup bond pads is disposed on individual blocks. The blocks are isolated from each other by a dielectric material. The normal bond pads on the blocks correspond to the backup bond pads, and each normal bond pad is electrically connected with the corresponding backup bond pad.

### RELATED APPLICATIONS

The present application is based on, and claims priority from, Taiwan Application Serial Number 94123418, filed Jul. 11, 2005, the disclosure of which is hereby incorporated by reference herein in its entirety.

### BACKGROUND

1. Field of Invention

The present invention relates to a bond pad structure. More particularly, the present invention relates to a bond pad structure that can be reworked after a bond failure.

2. Description of Related Art

Access to an electrical connection with an external circuit is required for an IC chip to function properly, and an IC device has to be packaged to prevent damage from external force or environmental factors during conveyance or pick-and-place procedures. Electronic packaging allows an IC device to perform a predefined function under an organized structure and provides protection for it and therefore is a necessary process in integrated circuit production.

Wire bonding technology is commonly used in IC package processes. In a wire bonding process, a chip is positioned on a lead frame first, and an end of a bonding wire, which is a metal wire made of Al or Au, is press fitted on a pad of the chip. Then, the other end of the metal wire is press fitted on a pin of the lead frame. In the case of a bond failure, conventionally, the bonding wire has to be removed, which also removes the associated metal area on the pad. Therefore, the chip can only be abandoned and cost of waste is quite high.

For the foregoing reasons, there is a need for an improved bond pad structure, so that waste due to failures in wire bonding processes is reduced.

### SUMMARY

It is therefore an aspect of the present invention to provide a bond pad structure that can be reworked for wire bonding.

It is another aspect of the present invention to provide a bond pad structure for reducing discard of any wafer due to a failed wire bonding process.

In accordance with the foregoing and other aspects of the present invention, a bond pad structure is provided. The bond pad structure includes a plurality of normal bond pads, a conductive structure and a plurality of backup bond pads. The conductive structure has a plurality of blocks isolated from each other by a dielectric material, and each of the normal bond pads is located on one of the blocks. At least one of the backup bond pads is disposed on individual blocks, and the normal bond pads correspond to and are electrically connected with the backup bond pads so that the backup bond pad can provide reworkability for wire bonding in a wire bonding process.

According to a preferred embodiment, the conductive structure is a top metal layer and both of the normal bond pad and the backup bond pad are disposed at an opening of a passivation layer, which is on the top metal layer. Each normal bond pad and the corresponding backup bond pad are disposed on the same block so that an electrical connection between both is allowed by the conductive structure.

According to another preferred embodiment, each block includes a normal bond pad area and at least a backup bond pad area, and both areas are isolated by a dielectric material. The normal bond pad area and the backup bond pad area adhere to a normal bond pad and a backup bond pad respectively so that two bond pads are electrically connected through the conductive structure and an interconnection structure beneath.

In conclusion, the bond pad structure of the invention provides a chance to rework in a wire bonding process without any added special process. Compared to a conventional pad structure with only one bond pad for wire bonding, the backup bond pad in the present invention is able to implement the same I/O behavior as the normal bond pad to avoid discard of a wafer due collateral removal or damage of the normal bond pad when a wire bonding fails in a process. One more chance to wire bond is available and financial resources can be saved considerably.

It is to be understood that both the foregoing general description and the following detailed description are by examples and are intended to provide further explanation of the invention as claimed.

### BRIEF DESCRIPTION OF THE DRAWINGS

These and other features, aspects and advantages of the present invention will become better understood with regard to the following description, appended claims and accompanying drawings where:

FIG. 1 is a schematic diagram of a chip with backup pads in accordance with a preferred embodiment of the present invention;

FIG. 2A is a cross-sectional view along line A-A in FIG. 1;

FIG. 2B is a cross-sectional view along line B-B in FIG. 1;

FIG. 3 is another aspect of a cross-sectional view along line A-A in FIG. 1;

FIG. 4A is a schematic diagram of a chip with backup pads in accordance with another preferred embodiment of the present invention; and

FIG. 4B is a cross-sectional view along line B-B in FIG. 4A.

### DESCRIPTION OF THE PREFERRED EMBODIMENTS

The present invention discloses a bond pad structure, which is defined by at least two bond pads on a conductive structure, wherein two bond pads are electrically connected through the conductive structure and have an identical input/output behavior. Reworkability is provided by an extra backup bond pad during a wire bonding process so that wafer discarding is reduced.

Reference will now be made in detail to the present preferred embodiments of the invention, examples of which are illustrated in the accompanying drawings. Wherever possible, the same reference numbers are used in the drawings and the description to refer to the same or like parts.

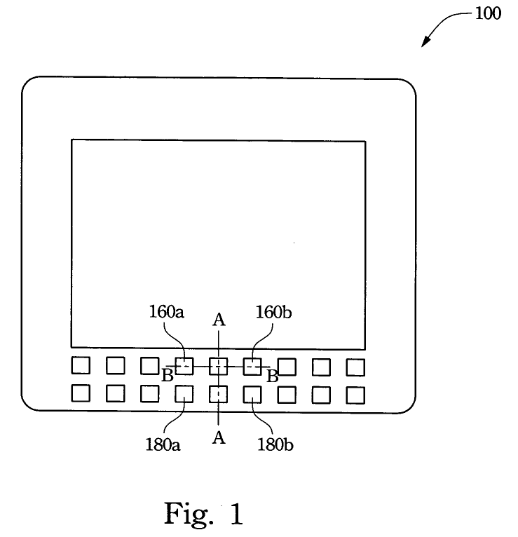

FIG. 1 is a schematic diagram of a semiconductor chip 100 with backup pads in accordance with a preferred embodiment of the present invention. The chip 100 has a plurality of normal bond pads such as normal bond pads 160a and 160b and corresponding backup bond pads 180a and 180b. Each backup bond pad is electrically connected with the corresponding normal bond pad.

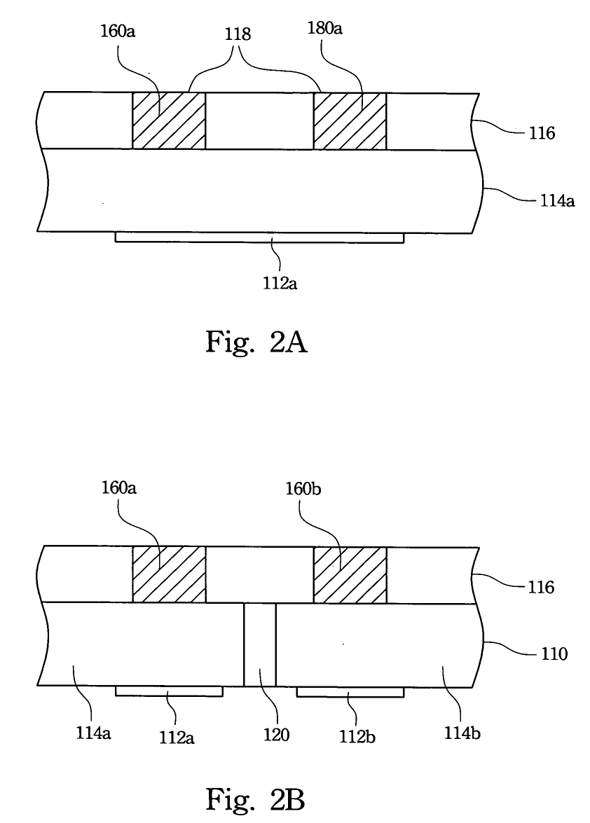

Reference is also made to FIGS. 2A and 2B, which illustrate cross-sectional views along line A-A and line B-B respectively in FIG. 1. The bond pad structure of the present invention includes a plurality of normal bond pads 160a and 160b, a conductive structure 110, and a plurality of backup bond pads 180a and 180b. The conductive structure 110 has a plurality of blocks 114a and 114b, and at least one of the backup bond pads is located on the individual block. Blocks are isolated from each other by a dielectric material 120, and the normal bond pads 160a and 160b are correspondingly located on the blocks 114a and 114b and therefore electrically connected with the backup bond pads 180a and 180b, respectively.

In the embodiment, the conductive structure 110 formed beneath a passivation layer 116 is a top metal layer known in the art, as shown in FIG. 2, and is defined by a plurality of blocks 114a and 114b which are separated from each other by the dielectric material 120. Blocks 114a and 114b contact the normal bond pads 160a and 160b and an interconnection structure 112a and 112b, correspondingly.

FIG. 2A illustrates a cross-sectional view along line A-A in FIG. 1, which also shows a structure of the block 114a. The passivation layer 116 has a plurality of openings 118. Contact surfaces of the openings 118 with respect to the block 114a are electrically connected due to the conductive structure 110. The normal bond pad 160a and the first backup bond pad 180a are located at the individual openings 118, both of which contact the conductive structure 110.

In the embodiment, the bond pad structure includes a passivation layer 116, a normal bond pad 160a, a first backup bond pad 180a and a top metal layer, as shown by the cross section of the block 114a. The block 114a is disposed on an interconnection structure 112a, which includes several material layers (not shown) that are generally a stack of several metal layers and dielectric layers. The dielectric layers are disposed between the metal layers and may also be between the block 114a and the metal layer in the case of the metal layers being a top layer of the interconnection structure 112a. Each dielectric layer includes at least a plug (not shown in the figure) for an electrical connection between metal layers and between the block 114a and the metal layer.

The dielectric material has a low dielectric constant preferably, and the metal layers may be copper. The passivation layer may be a layer including SiO₂ or silicon nitride. The plug may be copper or tungsten and the bond pad may be made of aluminum or aluminum-copper alloy.

Because the top metal layer is electrically connected with both of the normal bond pad 160a and the first backup bond pad 180a, the normal bond pad 160a can be used to connect an external circuit (not shown) first in a wire bonding process. When the process is finished successfully, the first backup bond pad 180a has no impact on the electric conduction of the whole structure, and an electrical signal is transmitted through the normal bond pad to the external circuit.

When a failure occurs in the process, a bonding wire bonded on the normal bond pad 160 has to be removed, which collaterally results in a removal of at least a portion of the normal bond pad 160a and causes it to be useless. In such case, the first backup bond pad 180a can be used for a backup and the wire bonding process can be implemented again for the identical chip. After a successful second (reworked) wire bonding, the electric signal is transmitted through the first backup bond pad 180a.

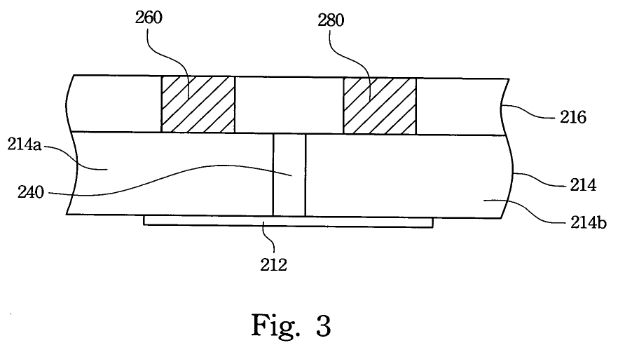

Reference is now made to FIG. 3, which illustrates another cross-sectional view along line A-A in FIG. 1 to describe another aspect of the aforementioned embodiment. A block 214 beneath the passivation layer 216 includes a normal bond pad area 214a and at least a backup bond pad area 214b, and the normal bond pad area 214a is isolated from the backup bond pad area 214b by a dielectric material 240. Each normal bond pad is disposed on the corresponding normal bond pad area, and at least a backup bond pad is disposed on each individual backup bond pad area. For example, the normal bond pad area 214a and the backup bond pad area 214b respectively adhere to a normal bond pad 260 and a backup bond pad 280; therefore, the normal bond pad 260 is electrically connected to an interconnection structure 212 beneath the block 214.

In the same way, when a successful wire bonding is achieved by the normal bond pad 260, the electrical signal is transmitted through the interconnection structure 212, the normal bond pad area 214a and the normal bond pad 260. The backup bond pad 280 still does not affect the electrical conduction in the whole bond pad structure. On the other hand, when a failure occurs in the wire bonding process with the normal bond pad 260, and the bonding wire is therefore removed, the backup bond pad 280 is used for a backup. In such case, the electrical signal is transmitted through the interconnection structure 212, the backup bond pad area 214b and the backup bond pad 280, no matter whether structural damage is caused of the normal bond pad area 214a bonded to the normal bond pad 260. Therefore, not only an opportunity to rework but a better reliability of the chip is obtained.

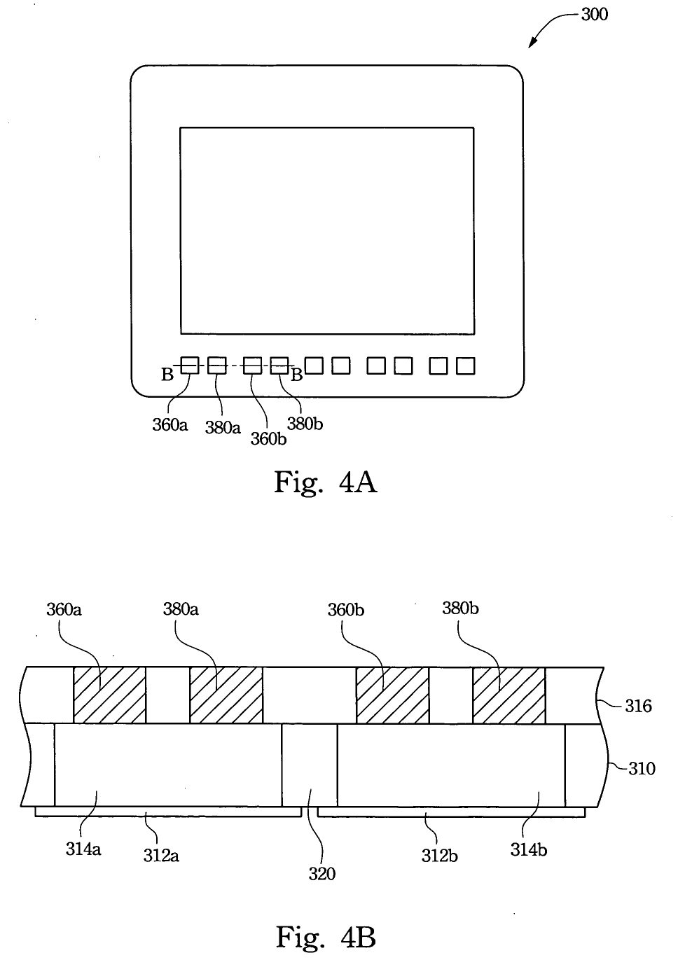

It should be noted that the arrangement of the normal bond pad and the backup bond pad above is changeable depending on process demand; it is not limited to the embodiment. Reference is now made to FIGS. 4A and 4B. FIG. 4A illustrates a schematic diagram of a chip with backup pads in accordance with another preferred embodiment of the present invention, which presents another version of arrangement of the bond pads. FIG. 4B is a cross-sectional view along line B-B in FIG. 4A, of which a conductive structure 310 is formed beneath a passivation layer 316 and has a plurality of blocks 314a and 314b isolated from each other by a dielectric material 320. Each block has a normal bond pad and a backup bond pad. The block 314a has a normal bond pad 360a and a backup bond pad 380a, and the block 314b has a normal bond pad 360b and a backup bond pad 380b. Each set of the normal bond pad and the corresponding backup bond pad are electrically connected through an interconnection structure such as 312a and 312b respectively, wherein the interconnection structures 312a and 312b are located beneath the blocks 314a and 314b.

The present invention has at least the following advantage. In the bond pad structure with a plurality of bond pads of the invention, each of the normal and backup bond pads is able to allow an electric connection to an external circuit with the same input/output behavior, so that the backup bond pad can be used for the same function when the normal one is removed in an unsuccessful wire bonding. The present invention reduces discarding wafers due to a failed wire bonding and provides much benefit in the back-end process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bond pad structure for providing a rework opportunity for wire bonding, comprising:
a conductive structure having a plurality of blocks isolated from each other by a dielectric material,
a plurality of normal bond pads on the blocks; and
a plurality of backup bond pads disposed on the blocks and corresponding to the normal bond pads,
wherein each of the backup bond pads is electrically connected with the corresponding normal bond pads to provide the rework opportunity for wire bonding when the corresponding normal bond pad is destroyed in a wire bonding process.

2. The bond pad structure of claim 1, wherein the conductive structure is a metal layer.

3. The bond pad structure of claim 1, wherein the amount of the backup bond pads is one or two.

4. The bond pad structure of claim 1, wherein the bond pads are made of aluminum or aluminum-copper alloy.

5. The bond pad structure of claim 1, wherein the conductive structure is made of copper.

6. The bond pad structure of claim 1, wherein the dielectric material is a low dielectric constant material.

7. The bond pad structure of claim 1, further comprising an interconnection structure beneath the conductive structure.

8. A bond pad structure for providing a rework opportunity for wire bonding, comprising:
a top metal layer having a plurality of blocks isolated from each other by a dielectric material,
a plurality of normal bond pads on the blocks; and
a plurality of backup bond pads disposed on the blocks and corresponding to the normal bond pads,
wherein each of the backup bond pads is electrically connected with the corresponding normal bond pads on the blocks to provide the rework opportunity for wire bonding when the corresponding normal bond pad is destroyed in a wire bonding process.

9. The bond pad structure of claim 8, wherein the bond pads are made of aluminum or aluminum-copper alloy.

10. The bond pad structure of claim 8, wherein the top metal layer is made of copper.

11. The bond pad structure of claim 8, wherein the dielectric material is a low dielectric constant material.

12. The bond pad structure of claim 8, further comprising an interconnection structure beneath the top metal layer.

13. A bond pad structure, comprising:
a plurality of normal bond pads; and
a top metal layer having a plurality of blocks isolated from each other by a dielectric material, wherein each of the blocks comprises:
a normal bond pad area, wherein the each of the normal bond pads is disposed on the normal bond pad areas correspondingly; and
a backup bond pad area having at least a backup bond pad thereon and isolated from the corresponding normal bond pad area by the dielectric material,
wherein each of the blocks adheres to an interconnection structure and each of the normal bond pads is electrically connected with the backup bond pad correspondingly through the interconnection structure.

14. The bond pad structure of claim 13, further comprising a passivation layer disposed on the top metal layer and having a plurality of the openings, wherein the bond pads are disposed at the openings and the passivation layer includes SiO₂ or silicon nitride.

15. The bond pad structure of claim 13, wherein the bond pads are made of aluminum or aluminum-copper alloy.

16. The bond pad structure of claim 13, wherein the top metal layer is made of copper.

17. The bond pad structure of claim 13, wherein the dielectric material is a low dielectric constant material.
